(19) United States
(12) Patent Application Publication
(10) Pub. No.: US 2015/0014754 A1
(43) Pub. Date: Jan. 15, 2015

(54) IMAGE SENSOR AND METHOD FOR MANUFACTURING THE SAME

(71) Applicant: LG Siltron Inc., Gyeongsangbuk-do (KR)

(72) Inventor: Hongkang Lim, Gyeongsangbuk-do (KR)

(21) Appl. No.: 14/379,280

(22) PCT Filed: Nov. 29, 2012
(86) PCT No.: PCT/KR2012/010241

§ 371 Date: Aug. 15, 2014

(30) Foreign Application Priority Data
Feb. 29, 2012 (KR) 10-2012-0021153

(51) Int. Cl. H01L 27/146; H01L 31/036

(52) U.S. Cl. CPC H01L 27/14645; H01L 27/14627; H01L 31/036; H01L 27/14687
USPC 257/292; 438/70

(57) ABSTRACT

Provided are an image sensor and a method of manufacturing the same. The image sensor includes a support substrate, a wire layer disposed under the support substrate, an epitaxial layer disposed under the wire layer, and a photodiode disposed in the epitaxial layer. The epitaxial layer has an off angle of about 0.3° to about 1.5° with respect to a [001] crystal orientation.

### CROSS-REFERENCE TO RELATED APPLICATIONS

The present application is a national phase application of PCT application PCT/KR2012/010241 filed Nov. 29, 2012, which claims the priority benefit of Korean patent application 10-2012-0021153 filed Feb. 29, 2012, the disclosures of which are incorporated herein by reference.

### BACKGROUND OF THE INVENTION

1. Technical Field

Embodiments relate to an image sensor and a method of manufacturing the same.

2. Background Art

In recent years, CMOS image sensors are in the spotlight as next generation image sensors. Such a CMOS image sensor is a device that sequentially detects outputs through MOS transistors in a switching manner. The MOS transistors are formed on a semiconductor substrate as many as the number of unit pixels according to a CMOS technology where a control circuit and a signal processing circuit are used as a peripheral circuit. That is, CMOS image sensor includes a photodiode and a MOS transistor formed in a unit pixel and obtains an image by sequentially detecting electrical signals of unit pixels in a switching manner.

The CMOS image sensor uses the CMOS fabrication technology, and thus has advantages such as low power consumption, a simple fabrication process due to the small number of photolithography processes, etc. In addition, since the CMOS image sensor can integrate a control circuit, a signal processing circuit, an analog/digital converter circuit, etc., into a CMOS image sensor chip, it is easy to miniaturize products employing the CMOS image sensor. Accordingly, the CMOS image sensor has been widely used for various products such as digital still cameras and digital video cameras.

In general, in case of a pixel having low resolution and a semiconductor design rule which is not fine, an image sensor having a front side illumination (FSI) structure is used. However, as the semiconductor design rule becomes very fine, and the CMOS image sensor has high resolution, it is difficult to secure an amount of light incident into a photodiode and a light transmission path. Accordingly, a CMOS image sensor having a back side illumination (BSI) structure in which a color filter and a lens are formed on a back surface of a wafer has been developed.

The BSI CMOS image sensor manufactured as described above may overcome disadvantage of the FSI CMOS image sensor and be advantageous for realizing high definition due to high sensitivity thereof. However, since the BSI CMOS image sensor uses a method in which the back surface of the wafer is processed to receive light, the CMOS image sensor may have difficulty in manufacturing through semiconductor processes and low yield.

Also, impurities should be completely removed in a region in which the photodiode is formed and a silicon single crystal region on the back surface of the wafer. Here, an epitaxy wafer rather than a polished wafer may be generally used as a substrate for the CMOS image sensor.

### SUMMARY OF THE PRESENTLY CLAIMED INVENTION

Embodiments provide an image sensor having less defects and improved performance and a method of manufacturing the same.

In one embodiment, an image sensor includes: a support substrate; a wire layer disposed under the support substrate; an epitaxial layer disposed under the wire layer; and a photodiode disposed in the epitaxial layer, wherein the epitaxial layer has an off angle of about 0.3° to about 1.5° with respect to a [001] crystal orientation.

In another embodiment, a method of manufacturing an image sensor, the method includes: providing a silicon wafer having an off angle of about 0.3° to about 1.5° with respect to a [001] crystal orientation; forming an epitaxial layer on the silicon wafer; forming a photodiode on the epitaxial layer; forming a wire layer on the epitaxial layer; forming a support substrate on the wire layer; and removing the silicon wafer.

According to the embodiment, the image sensor has an off angle of 0.3° to 1.5° with respect to a [001] crystal orientation. In this case, defects of the epitaxial layer are remarkably reduced.

Thus, the image sensor according to the embodiment can reduce the defects and can have an improved sensing efficiency.

### BRIEF DESCRIPTION OF THE DRAWINGS

FIG. 1 is a view illustrating a process of growing an ingot for forming a silicon wafer.

FIG. 2 is a view illustrating a process of forming an epitaxial layer on a silicon wafer.

FIGS. 3 to 8 are views illustrating a process of manufacturing an image sensor according to an embodiment.

FIG. 9 is a view illustrating the number of defects according to an off angle of an epitaxial layer.

FIG. 10 is a view illustrating a defect rate of the image sensor according to an off angle of a silicon wafer.

### DETAILED DESCRIPTION

In the description of embodiments, it will be understood that when a substrate, pattern, region, or layer is referred to as being ‘on’ or ‘under’ another substrate, pattern, region, or layer, the terminology of ‘on’ and ‘under’ includes both the meanings of ‘directly’ and ‘indirectly’.

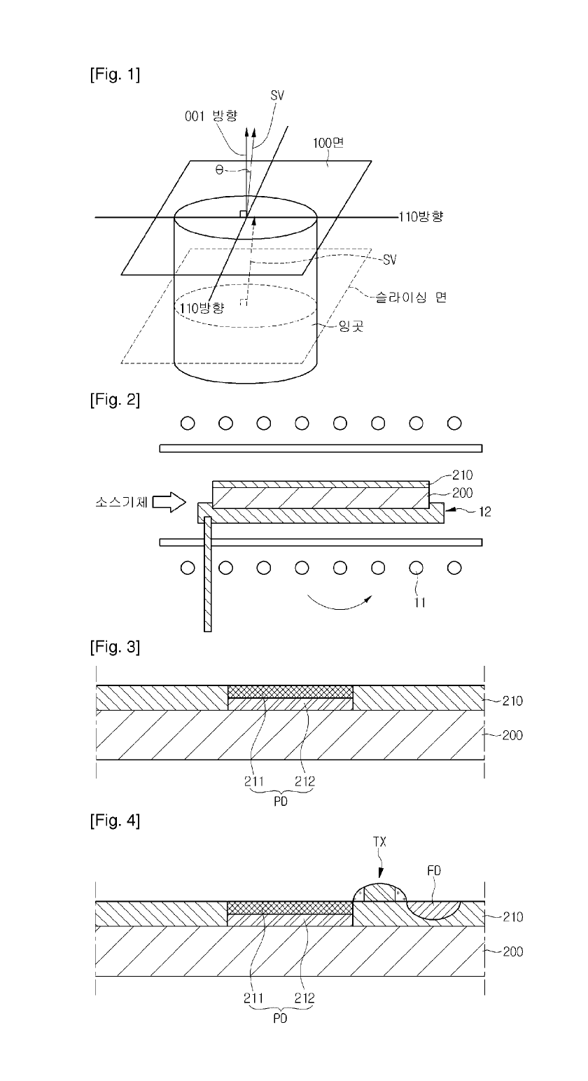

FIG. 1 is a view illustrating a process of growing an ingot for forming a silicon wafer.

Referring to FIG. 1, a silicon ingot is grown. The silicon ingot may be grown in a [001] crystal orientation. That is, an extension direction of the silicon ingot may be the [001] crystal orientation.

Thereafter, the silicon ingot is sliced in a plurality of wafers through a slicing process such as a wire sawing process. At this time, an off angle θ of each of wafers may be determined.

That is, the silicon ingot may be sliced in a direction tilted with respect to a [100] plane. The silicon ingot may be sliced in a direction tilted at a predetermined off angle θ with respect to the [100] plane.

Here, the silicon ingot is sliced to have an off angle θ of about 0.3° to about 1.5°, thereby forming a plurality of wafers 200.

In more detail, the silicon ingot may be sliced in a direction tilted at a narrower off angle θ of about 0.3° to about 0.7°.

That is, the off angle θ is an angle between the [001] crystal orientation of the silicon ingot and a direction perpendicular to the sliced surface. The [001] crystal orientation is a direction perpendicular to the [100] plane. That is, the off angle θ is an angle between the direction perpendicular to the sliced surface and the [001] crystal orientation.

Thereafter, the silicon wafer 200 may be polished through a polishing process so that the silicon wafer 200 is suitable for additional processes. As described above, the silicon wafer 200 may have an off angle θ of about 0.3° to about 1.5°. Furthermore, the silicon wafer 200 may have an off angle θ of about 0.3° to about 0.7°.

The off angle θ of the silicon wafer 200 is an angle between a top surface of the wafer and the [100] plane of the silicon wafer 200. That is, the off angle θ of the silicon wafer 200 is an angle between a straight line perpendicular to a top surface of the wafer and the [001] crystal orientation of the silicon wafer 200. That is, the off angle θ of the silicon wafer 200 may represent an angle tilted with respect to the [001] crystal orientation regardless of an X axis and a Y axis.

Also, the silicon wafer 200 may be a p-type silicon wafer. Alternatively, the silicon wafer 200 may be an n-type silicon wafer.

The silicon wafer 200 may have a resistance of about 0.005 Ω·cm to about 0.02 Ω·cm.

FIG. 2 is a view illustrating a process of forming an epitaxial layer on a silicon wafer.

Referring to FIG. 2, in a method of forming an epitaxial layer on a wafer, the silicon wafer 200 is disposed within an apparatus for growing an epitaxial layer 210 (hereinafter, referred to as an “epitaxial layer growth apparatus”) to form an epitaxial layer 210. The epitaxial layer growth apparatus includes a heater 11 and a susceptor 12. The heater 11 heats the silicon wafer 200. At this time, the susceptor 12 supports the silicon wafer 200.

As described above, in the state where the silicon wafer 200 is heated, a source gas is supplied onto the silicon wafer 200. Silicon tetrachloride may be used as the source gas for growing the epitaxial layer 210. Diborane (B₂H₆) may be used as a gas for injecting a dopant into the epitaxial layer 210. Also, hydrogen gas may be used as a carrier gas.

Accordingly, p-type impurities may be doped into the epitaxial layer 210. Here, the silicon wafer 200 may also be a p-type silicon wafer.

Alternatively, n-type impurities may be doped into the epitaxial layer 210. Here, the silicon wafer 200 may also be an n-type silicon wafer.

In a process for growing the epitaxial layer 210, a silicon epitaxial process for growing the epitaxial layer 200 may be performed under a temperature of about 1,100° C. to about 1,200° C. and a process pressure corresponding to an atmospheric pressure.

Since the epitaxial layer 210 is formed by the epitaxial process, the epitaxial layer 210 may have the same crystal structure as the silicon wafer 200. Accordingly, the epitaxial layer 210 may have an off angle θ of about 0.3° to about 1.5° or about 0.3° to about 0.7°.

Also, the epitaxial layer 210 may have a thickness of about 1 μm to 20 μm. The epitaxial layer 210 may have a resistance of about 1 Ω·cm to about 10 Ω·cm.

Hereinafter, a method of manufacturing an image sensor according to an embodiment will be described with reference to the accompanying drawings.

FIGS. 3 to 8 are views illustrating a process of manufacturing an image sensor according to an embodiment.

Referring to FIG. 3, a photodiode PD is formed on the epitaxial layer 210. Low-concentration impurities may be selectively injected into the epitaxial layer 210 to form the photodiode PD. For example, low-concentration n-type and p-type impurities may be injected with depths different from each other to form the photodiode PD. The photodiode PD includes a region 211 in which the low-concentration n-type impurities are doped and a region 212 in which the low-concentration p-type impurities are doped.

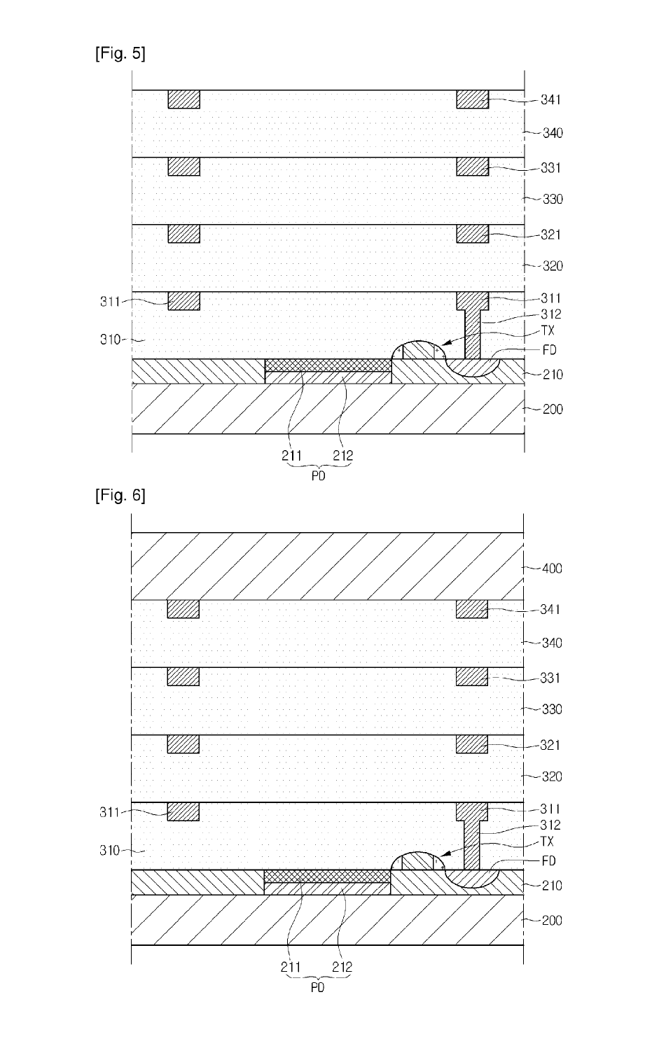

Referring to FIG. 4, a plurality of transistors are formed on the epitaxial layer 210. Also, high conductive impurities may be injected into the epitaxial layer 210 to form a floating diffusion layer FD. Although a transfer transistor Tx connected to the photodiode PD is illustrated in FIG. 4, the present disclosure is not limited thereto. For example, more transfer transistors Tx may be formed on the epitaxial layer 210. For example, a reset transistor, a select transistor, and an access transistor may be further formed on the epitaxial layer 210.

The transfer transistor Tx and the reset transistor are connected to the photodiode PD in series. A source of the transfer transistor Tx is connected to the photodiode PD, and a drain of the transfer transistor Tx is connected to a source of reset transistor. A power source voltage Vdd is applied to a drain of the reset transistor.

The drain of the transfer transistor Tx serves as the floating diffusion layer FD. The floating diffusion layer FD is connected to a gate of the select transistor. The select transistor and the access transistor are connected to each other in a series. That is, a source of the select transistor and a drain of the access transistor are connected to each other. The power source voltage Vdd is applied to the drain of the access transistor and the source of the reset transistor. The drain of the select transistor corresponds to an output terminal Out. A select signal Row is applied to the gate of the select transistor.

An operation of the image sensor having the above-described structure will be simply described. First, after the reset transistor is turned on so that an electrical potential of the floating diffusion layer FD is equal to the power source voltage Vdd, the reset transistor is turned off. This operation is defined as a reset operation.

When external light is incident into the photodiode PD, electron-hole pairs (EHP) are generated within the photodiode PD to accumulate signal charges within the photodiode PD. Then, the transfer transistor Tx is turned on, and signal charges accumulated within the photodiode PD are outputted into the floating diffusion layer FD and stored in the floating diffusion layer FD. Thus, the electrical potential of the floating diffusion layer FD is charged in proportion to an amount of electric charges outputted from the photodiode PD. As a result, the gate of the access transistor may be changed in electrical potential. When the select transistor is turned on by the select signal Row, data is output into the output terminal Out. After the data is output, a pixel P performs the reset operation again. The image sensor according to the embodiment repeatedly performs the above-described processes to convert light into an electrical signal and thus output the converted the electrical signal.

Referring to FIG. 5, a plurality of wire layers 310, 320, 330, and 340 are formed on the epitaxial layer 210. For example, the plurality of wire layers 310, 320, 330, and 340 may include a first wire layer 310, a second wire layer 320, a third wire layer 330, and the fourth wire layer 340.

The wire layers 310, 320, 330, and 340 may further include wires and vias. The wires are disposed within interlayer dielectrics included in each of the wire layers 310, 320, 330, and 340, respectively. The first wire layer 310 includes first wires 311 and first vias 312. The second wire layer 320 includes second wires 321 and second vias. The third wire layer 330 includes third wires 331 and third vias. The fourth wire layer 340 includes fourth wires 341 and fourth vias.

The wire layers 310, 320, 330, and 340 may be formed through a dual damascene process. That is, a groove may be formed in an interlayer dielectric, a conductive material such as cupper (Cu) may be filled into the groove, and a chemical mechanical polishing process may be preformed to the wire layers 310, 320, 330, and 340.

Referring to FIG. 6, a support substrate 400 is formed on the wire layers 310, 320, 330, and 340. The support substrate 400 supports the epitaxial layer 210 and the wire layers 310, 320, 330, and 340. That is, the support substrate 400 may have strength enough to support the epitaxial layer 210 and the wire layers 310, 320, 330, and 340. The support substrate 400 may be a silicon substrate, a metal substrate, a plastic substrate, or a glass substrate.

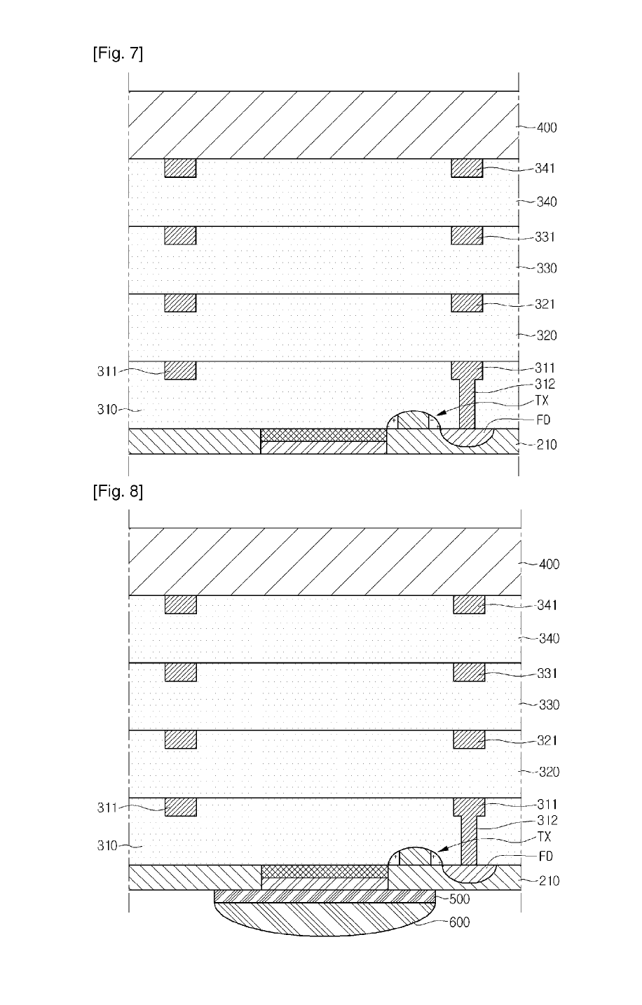

Referring to FIG. 7, the silicon wafer 200 is removed. The silicon wafer 200 is removed by chemical and mechanical processes. For example, the silicon wafer 200 is removed by an etching process using an etching liquid after the silicon wafer 200 is mechanically sliced. Also, a chemical mechanical polishing process may be further performed to remove the silicon wafer 200.

Referring to FIG. 8, a color filter 500 is disposed under the epitaxial layer 210. An overcoating layer may be further disposed between the color filter 500 and the epitaxial layer 210. The color filter 500 may include a colored pigment or dye. The color filter 500 may filter light having a specific color.

A micro lens 600 is formed under the color filter 500. The micro lens 600 is formed through a reflow process and has a convex shape.

As described above, the image sensor according to the embodiment includes the support substrate 400, the wire layers 310, 320, 330, and 340 disposed under the support substrate 400, the epitaxial layer 210 disposed under the wire layers 310, 320, 330, and 340, and the photodiode PD disposed within the epitaxial layer 210.

Here, the epitaxial layer 210 has an off angle θ of about 0.3° to about 1.5°. When the epitaxial layer 210 has the off angle θ of about 0.3° to about 1.5°, the epitaxial layer 210 may be significantly decreased in defects. Thus, the image sensor according to the embodiments may be decreased in defects and have improved sensing efficiency.

Particularly, to form the image sensor according to the embodiment, various ions may be injected into the epitaxial layer 210. For example, to form the photodiode PD in the epitaxial layer 210, the n-type impurities and/or the p-type impurities are injected into the epitaxial layer 210.

Here, characteristics and performance of the photodiode PD may be decided according to the injected concentration and depth of the ions. Also, since the off angle θ of the epitaxial layer 210 is minutely adjusted, the defects and the characteristic changes occurring when the ion injection process is performed may be controlled. That is, in the method for manufacturing of the image sensor according to the embodiment, the off angle θ may be adjusted to restrict the defects or the characteristic changes occurring when the ion injection process is performed.

Also, in the image sensor according to the embodiment, the silicon wafer 200 is removed, and then light may be incident through the back surface of the image sensor. Thus, in the image sensor according to the embodiment, light may be incident into the photodiode PD with a short light path. In addition, the image sensor may have the improved sensing efficiency.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### Experimental Example

A silicon ingot having various off angles and a diameter of about 300 mm is grown, and then a slicing and polishing process are performed to form a silicon wafer. Thereafter, an epitaxial layer having a thickness of about 1 μm to about 20 μm is formed using silicon tetrachloride as a source gas and using B₂H₆ as dopant gas. Thereafter, n-type impurities are injected into the epitaxial layer to form a photodiode. Thereafter, a dual damascene process is performed on the epitaxial layer to form four wire layers. Thereafter, a wafer that is a support substrate is attached to the uppermost wire layer, and the silicon wafer is removed. Then, a color filter and a micro lens are formed under the epitaxial layer.

### Result

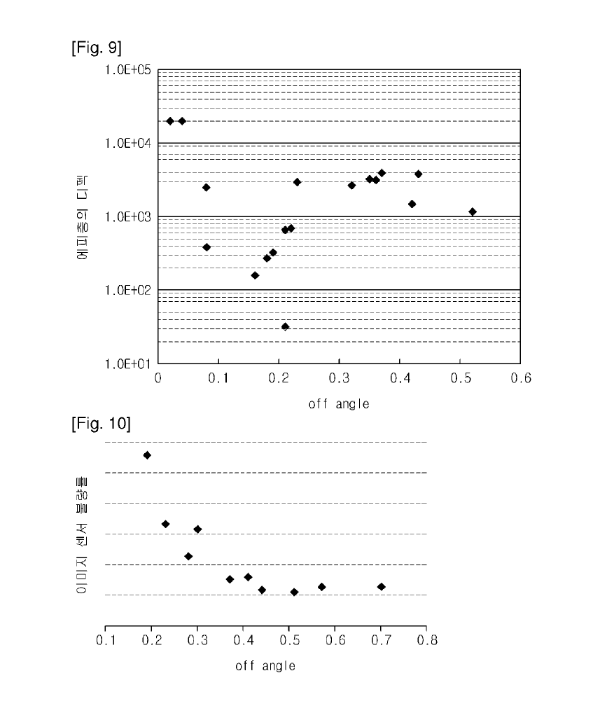

As described above, the defects and defect rates of the epitaxial layer formed according the off angle and the image sensor are illustrated in FIGS. 9 and 10. FIG. 9 is a view illustrating the number of defects according to an off angle of an epitaxial layer. FIG. 10 is a view illustrating a defect rate of the image sensor according to an off angle of a silicon wafer.

As shown in FIG. 9 and FIG. 10, when the off angle is about 0.3° to about 0.7°, the defect rate of the image sensor is reduced.

### INDUSTRIAL APPLICABILITY

Since the embodiment can be applied to an image sensor and a method of manufacturing the same, industrial applicability may be significantly high.

What is claimed is:

1. An image sensor comprising:
a support substrate;
a wire layer disposed under the support substrate;
an epitaxial layer disposed under the wire layer; and
a photodiode disposed in the epitaxial layer,
wherein the epitaxial layer has an off angle of about 0.3° to about 1.5° with respect to a [001] crystal orientation.

2. The image sensor according to claim 1, wherein the epitaxial layer has an off angle of about 0.3° to about 0.7° with respect to the [001] crystal orientation.

3. The image sensor according to claim 1, further comprising a transfer transistor disposed on the epitaxial layer, the transfer transistor being connected to the photodiode.

4. The image sensor according to claim 1, further comprising a color filter disposed under the epitaxial layer.

5. The image sensor according to claim 4, further comprising a micro lens disposed under the color filter.

6. The image sensor according to claim 1, wherein the epitaxial layer has a resistance of about 1 Ω·cm to about 10 Ω·cm.

7. A method of manufacturing an image sensor, the method comprising:
providing a silicon wafer having an off angle of about 0.3° to about 1.5° with respect to a [001] crystal orientation;
forming an epitaxial layer on the silicon wafer;
forming a photodiode on the epitaxial layer;
forming a wire layer on the epitaxial layer;
forming a support substrate on the wire layer; and
removing the silicon wafer.

8. The method according to claim 7, further comprising forming a color filter under the epitaxial layer after the removing of the silicon wafer.

9. The method according to claim 8, further comprising forming a micro lens under the color filter.

10. The method according to claim 7, wherein the silicon wafer has an off angle of about 0.3° to about 0.7° with respect to a [001] crystal orientation.

11. The method according to claim 7, wherein the silicon wafer has a resistance of about 0.005 Ω·cm to about 0.02 Ω·cm.

12. The method according to claim 7, wherein the epitaxial layer has a resistance of about 1 Ω·cm to about 10 Ω·cm.
